(19) United States
(12) Patent Application Publication
(10) Pub. No.: US 2026/0173869 A1
(43) Pub. Date: Jun. 18, 2026

(54) PACKAGE STRUCTURE AND METHOD FOR FORMING THE SAME

(71) Applicant: JCET Group Co., LTD., Jiangyin (CN)

(72) Inventor: Feng LI, Jiangyin (CN)

(21) Appl. No.: 19/406,491

(22) Filed: Dec. 2, 2025

(30) Foreign Application Priority Data
Dec. 13, 2024 (CN) 202411837318.5

(51) Int. Cl. H10W 40/20; H01F 27/28

(52) U.S. Cl. CPC H10W 40/235; H01F 27/2804; H10W 40/233; H10W 70/65; H10W 90/724

(57) ABSTRACT

A package structure and a method for forming the same are provided. The package structure includes: a substrate including a front surface and a back surface oppositely disposed along a first direction; an inductor structure including: a first main surface and a second main surface oppositely disposed along a second direction, and a side surface located between the first main surface and the second main surface, where the side surface of the inductor structure is mounted on the front surface of the substrate along the first direction, and the second direction is perpendicular to the first direction; a first functional chip mounted on the first main surface of the inductor structure; and a second functional chip mounted on the second main surface of the inductor structure.

### CROSS-REFERENCE TO RELATED APPLICATIONS

This application claims the benefit of priority to Chinese Application No. 202411837318.5, filed Dec. 13, 2024, which is incorporated herein by reference in its entirety.

### TECHNICAL FIELD

The present application relates to the field of semiconductor manufacturing technology, and particularly relates to a package structure and a method for forming the same.

### BACKGROUND

In order to increase the integration level of the package structure, it is often necessary to integrate a plurality of chips within the same package structure.

An urgent technical problem that needs to be solved is how to reduce the size of the package structure that integrates a plurality of chips and improves the heat dissipation performance of the package structure, thus achieving the improvement of the performance and the extension of the service life of the package structure.

### SUMMARY

The present disclosure provides a package structure and a method for forming the same.

According to some embodiments, the present disclosure provides a package structure, including: a substrate including a front surface and a back surface oppositely disposed along a first direction; an inductor structure including a first main surface and a second main surface oppositely disposed along a second direction, as well as a side surface located between the first main surface and the second main surface, the side surface of the inductor structure being mounted on the front surface of the substrate along the first direction, and the second direction intersects perpendicularly with the first direction; a first functional chip mounted on the first main surface of the inductor structure; and a second functional chip mounted on the second main surface of the inductor structure.

In some embodiments, it further includes a wiring structure located inside the inductor structure and extending to the side surface of the inductor structure, the wiring structure is electrically connected to the first functional chip, the second functional chip, and the substrate.

In some embodiments, the inductor structure includes a magnetic material layer and a metal coil located within the magnetic material layer; and the wiring structure includes a metal wiring located within the magnetic material layer, a plurality of conductive connection pillars electrically connected to the metal wiring and exposed on the first main surface and the second main surface, and leads electrically connected to the metal wiring and exposed on the side surface of the inductor structure, the conductive connection pillars being electrically connected to the first functional chip and the second functional chip, the leads being electrically connected to the substrate.

In some embodiments, it further includes a first surface component mounted on at least the first main surface or the second main surface, and the first surface component is electrically connected to the conductive connection pillars.

In some embodiments, it further includes a heat dissipation structure covering at least on the surface of the first functional chip or the second functional chip facing away from the inductor structure along the second direction.

In some embodiments, the heat dissipation structure includes: a first side surface heat sink mounted on a surface of the first functional chip facing away from the inductor structure along the second direction; and a second side surface heat sink mounted on a surface of the second functional chip facing away from the inductor structure along the second direction.

In some embodiments, the heat dissipation structure further includes: an end heat sink located within the magnetic material layer and disposed on a side of the magnetic material layer facing away from the substrate along the first direction; and an internal heat sink located within the magnetic material layer, and one end being connected to the end heat sink and the other end extending out of the side surface of the inductor structure.

In some embodiments, the heat dissipation structure further includes a top heat sink, located, along the first direction on a side of the inductor structure facing away from the substrate, and the top heat sink continuously covers on the first side surface heat sink, the second side surface heat sink, and the end heat sink.

In some embodiments, it further includes: a molding layer, the molding layer molds at least the inductor structure, the first functional chip, and the second functional chip to form a magnetic module, the magnetic module being mounted on the front surface of the substrate; and a second surface component mounted on the front surface of the substrate, and the second surface component is located outside the magnetic module.

According to other embodiments, the present disclosure also provides a method for forming a package structure, including the following steps: forming an inductor structure, the inductor structure including a first main surface and a second main surface oppositely disposed along a second direction, as well as a side surface located between the first main surface and the second main surface; mounting a first functional chip onto the first main surface of the inductor structure and mounting a second functional chip onto the second main surface of the inductor structure; and mounting, in a direction in which the side surface of the inductor structure faces the front surface of the substrate, the inductor structure onto the front surface of the substrate, the substrate includes a front surface and a back surface oppositely disposed along a first direction, and the second direction intersects perpendicularly with the first direction.

In some embodiments, the steps for forming the inductor structure further include: forming a magnetic material layer, a metal coil located within the magnetic material layer, and a wiring structure located within the magnetic material layer, the magnetic material layer and the metal coil together serve as the inductor structure; the wiring structure includes a metal wiring located within the magnetic material layer, a plurality of conductive connection pillars electrically connected to the metal wiring and exposed on the first main surface and the second main surface, and leads electrically connected to the metal wiring and exposed on the side surface of the inductor structure.

In some embodiments, the steps for mounting a first functional chip onto the first main surface of the inductor structure and mounting a second functional chip onto the second main surface of the inductor structure include: mounting the first functional chip onto the first main surface of the inductor structure and electrically connecting the first functional chip with the conductive connection pillars exposed on the first main surface; and mounting the second functional chip onto the second main surface of the inductor structure and electrically connecting the second functional chip with the conductive connection pillars exposed on the second main surface.

In some embodiments, the steps of mounting the first functional chip onto the first main surface of the inductor structure and electrically connecting the first functional chip to the conductive connection pillar exposed on the first main surface further include: mounting a first surface component onto the first main surface of the inductor structure and electrically connecting the first surface component with the conductive connection pillars exposed on the first main surface.

In some embodiments, before mounting the second functional chip onto the second main surface of the inductor structure, the process further includes the following step: mounting a first side surface heat sink onto a surface of the first functional chip facing away from the inductor structure along the second direction.

In some embodiments, before mounting the second functional chip onto the second main surface of the inductor structure, the process further includes the following steps: forming a first molding layer molding the inductor structure, the first functional chip, and the first side surface heat sink.

In some embodiments, the steps for mounting the second functional chip onto the second main surface of the inductor structure include: mounting a second side surface heat sink onto a surface of the second functional chip facing away from the inductor structure along the second direction; and forming a second molding layer covering the first molding layer and molding the second functional chip and the second side surface heat sink, the first molding layer and the second molding layer together constitute a molding layer.

In some embodiments, after mounting the inductor structure onto the front surface of the substrate in a direction in which the side surface of the inductor structure faces the front surface of the substrate, it further includes the following steps: mounting a top heat sink on a side of the inductor structure facing away from the substrate, and the top heat sink continuously covers the first side surface heat sink, the second side surface heat sink, and the molding layer.

### BRIEF DESCRIPTION OF THE DRAWINGS

FIG. 1 is a cross-sectional schematic diagram of the package structure according to some implementations of the present disclosure;

FIG. 2 is a schematic diagram of the inductor structure and wiring structure according to some implementations of the present disclosure;

FIG. 3 is a flow schematic diagram of a method for forming the package structure according to some implementations of the present disclosure;

FIG. 4 is a schematic diagram after forming the inductor structure and wiring structure according to some implementations of the present disclosure;

FIG. 5 is a structural schematic diagram after a plurality of inductor structures are arranged on the first carrier board according to some implementations of the present disclosure;

FIG. 6 is a structural schematic diagram after the first functional chip is mounted on the first main surface of the inductor structure according to some implementations of the present disclosure;

FIG. 7 is a structural schematic diagram after the first side surface heat sink is mounted on the first functional chip according to some implementations of the present disclosure;

FIG. 8 is a structural schematic diagram after forming the first molding layer according to some implementations of the present disclosure;

FIG. 9 is a structural schematic diagram after mounting the second functional chip on the second main surface of the inductor structure according to some implementations of the present disclosure;

FIG. 10 is a structural schematic diagram after forming the second molding layer according to some implementations of the present disclosure; and

FIG. 11 is a structural schematic diagram of a single package unit according to some implementations of the present disclosure.

### DETAILED DESCRIPTION

The implementations of the package structure and the method for forming the same provided by the present disclosure will be described in detail in conjunction with the accompanying drawings.

As mentioned above; in order to increase the integration level of the package structure, it is often necessary to integrate a plurality of chips within the same package structure. Currently, in order to improve the integration level of the package structure, it is typically necessary to arrange a lower substrate and an upper substrate located above the lower substrate within the package structure, a plurality of chips are laid flat on the upper substrate, therefore, it is necessary to reserve more space on the upper substrate to facilitate the layout of the plurality of chips, which leads to an increase in the dimensions of the package structure. A plurality of copper pillars are arranged between the upper substrate and the lower substrate to electrically connect the upper substrate and the lower substrate, and perform signal transmission between the upper substrate and the lower substrate. The arrangement of the copper pillars not only increases the manufacturing difficulty of the package structure, but also leads to an increase in parasitic capacitance effects inside the package structure, which is not conducive to further improving and enhancing the performance of the package structure. In order to further expand the functionality of the package structure, a magnetic inductor is typically arranged between the upper substrate and the lower substrate, and the soldering between the magnetic inductor and the upper substrate as well as the lower substrate is achieved through solder. The heat dissipation channel of the package structure is typically arranged above the chip, but during actual operation of the package structure, heat primarily accumulates on the upper substrate and the magnetic inductor, so that it results in limited heat dissipation efficiency of the package structure, which is not conducive to improving the performance of the package structure and affects the service life of the package structure.

Therefore, an urgent technical problem that needs to be solved is how to reduce the size of the package structure that integrates a plurality of chips and improves the heat dissipation performance of the package structure, thus achieving the improvement of the performance and the extension of the service life of the package structure.

In the package structure and the method for forming the same provided by the present disclosure, by forming an inductor structure including a first main surface and a second main surface oppositely disposed along a second direction, as well as a side surface located between the first main surface and the second main surface, and by mounting the inductor structure on the front surface of the substrate in a direction in which the side surface of the inductor structure is opposed to the front surface of the substrate, the inductor structure is vertically mounted on the substrate; the first functional chip and the second functional chip are respectively mounted on the first main surface and the second main surface of the inductor structure; on the one hand, in the package structure integrating an inductor structure and a plurality of functional chips, there is no need to stack a plurality of substrates, which simplifies of the package structure; on the other hand, the inductor structure is vertically mounted on the substrate, thereby reducing the occupation of the substrate area, thus helping to further reduce the size of the package structure and improving the integration level of the package structure.

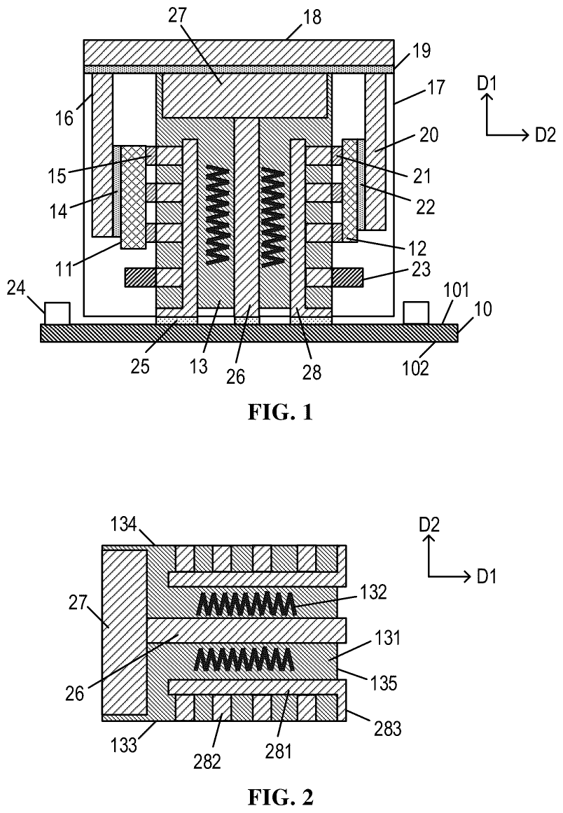

The present implementation provides a package structure, FIG. 1 is a cross-sectional schematic diagram of the package structure in some implementations of the present disclosure, and FIG. 2 is a schematic diagram of the inductor structure and wiring structure in some implementations of the present disclosure. As shown in FIGS. 1 and 2, the package structure includes: a substrate 10 including a front surface 101 and a back surface 102 oppositely disposed along a first direction D1; an inductor structure 13 including a first main surface 133 and a second main surface 134 oppositely disposed along a second direction D2, as well as a side surface 135 located between the first main surface 133 and the second main surface 134, the side surface 135 of the inductor structure 13 being mounted on the front surface 101 of the substrate 10 along the first direction D1, and the second direction D2 intersects perpendicularly with the first direction D1; a first functional chip 11 mounted on the first main surface 133 of the inductor structure 13; and a second functional chip 12 mounted on the second main surface 134 of the inductor structure 13.

In some implementations, the substrate 10 may be, but is not limited to a Printed Circuit Board (PCB). The inductor structure 13 is mounted on the front surface 101 of the substrate 10 in a direction in which the side surface 135 faces the front surface 101 of the substrate 10, thereby positioning the first main surface 133 and the second main surface 134 of the inductor structure 13 opposed to each other along a direction perpendicular to the front surface 101 of the substrate 10 (i.e., the second direction D2). In one example, the first functional chip 11 is flip-chip mounted on the first main surface 133 of the inductor structure 13, and the second functional chip 12 is flip-chip mounted on the second main surface 134 of the inductor structure 13, that is, both the first functional chip 11 and the second functional chip 12 are perpendicular to the front surface 101 of the substrate 10. The structure of the first functional chip 11 may be identical to or different from that of the second functional chip 12. In one example, the inductor structure 13 includes a magnetic inductor.

In the present implementation, by vertically mounting the inductor structure 13 on the front surface 101 of the substrate 10 (i.e., mounting the inductor structure 13, in a direction in which the side surface 135 faces the front surface 101 of the substrate 10, on the front surface 101 of the substrate 10), there is no need to stack a plurality of substrates in the package structure integrating an inductor structure and a plurality of functional chips, which simplifies the package structure. Moreover, the inductor structure is vertically mounted on the substrate, thereby reducing the occupation of the substrate area, thus helping to further reduce the size of the package structure and improving the integration level of the package structure. The first main surface 133 and the second main surface 134 of the inductor structure 13 are oppositely disposed along a direction perpendicular to the front surface 101 of the substrate 10 (i.e., the second direction D2), so that a plurality of functional chips or surface components can be mounted on the first main surface 133 and the second main surface 134, which helps to further reduce the size of the package structure while improving the integration level of the package structure.

In one example, a plurality of first functional chips 11 are mounted on the first main surface 133 of the inductor structure 13, and the plurality of first functional chips 11 are arranged at intervals along the first direction D1 to further improve the integration level of the package structure and expand the function and application field of the package structure. The structures of the plurality of first functional chips 11 mounted on the first main surface 133 may be the same or different. “The plurality of” in the present implementation refers to two or more.

In another example, a plurality of second functional chips 12 are mounted on the second main surface 134 of the inductor structure 13, and the plurality of second functional chips 12 are arranged at intervals along the first direction D1 to further improve the integration level of the package structure and expand the function and application field of the package structure.

In some embodiments, the package structure further includes: a wiring structure 28 located inside the inductor structure 13 and extending to the side surface 135 of the inductor structure 13, the wiring structure 28 is electrically connected to the first functional chip 11, the second functional chip 12, and the substrate 10.

In some implementations, by integrating at least a part of the wiring structure 28 into the interior of the inductor structure 13, there is no need to form a wire electrically connecting the first functional chip 11, the second functional chip 12, and the substrate 10 through wire bonding, thereby simplifying the manufacturing process of the package structure. Moreover, by integrating at least a part of the wiring structure 28 into the interior of the inductor structure 13, it helps to further reduce the size of the package structure and improve the space utilization efficiency inside the package structure.

In some embodiments, the inductor structure 13 includes a magnetic material layer 131 and a metal coil 132 located within the magnetic material layer 131.

The wiring structure 28 includes metal wiring 281 located within the magnetic material layer 131, a plurality of conductive connection pillars 282 electrically connected to the metal wiring 281 and exposed on the first main surface 133 and the second main surface 134, as well as leads 283 electrically connected to the metal wiring 281 and exposed on a side surface 135 of the inductor structure 13; the conductive connection pillars 282 are electrically connected to the first functional chip 11 and the second functional chip 12, and the leads 283 are electrically connected to the substrate 10. In one example, the material of the magnetic material layer 131 includes a magnetic material and a coating material, and the coating material is an organic polymer material or an inorganic material.

For example, the substrate 10 includes a substrate body and a redistribution layer located within the substrate body. The inductor structure 13 includes the magnetic material layer 131 and the metal coil 132 located within the magnetic material layer 131. In one example, the plurality of metal coils 132 are arranged within the inductor structure 13; FIGS. 1 and 2 illustrate an example where the inductor structure 13 has two metal coils 132 arranged at intervals along the second direction D2. The metal coils 132 are located in the middle area of the magnetic material layer 131, and the metal wiring 281 in the wiring structure 28 is located in the edge area of the magnetic material layer 131 to reduce the connection distance between the first functional chip 11 as well as the second functional chip 12, and the wiring structure 28. The wiring structure 28 includes the metal wiring 281 disposed at least in edge areas on two sides of the magnetic material layer 131 along the second direction D2, a plurality of conductive connection pillars 282 electrically connected to the metal wiring 281 and exposed on the first main surface 133 and the second main surface 134, and leads 283 connected to the ends of the metal wiring 281 and exposed on the side surface 135 of the inductor structure 13. The conductive connection pillars 282 exposed on the first main surface 133 are electrically connected to the first functional chip 11 through the first conductive bumps 15, and the conductive connection pillars 282 exposed on the second main surface 134 are electrically connected to the second functional chip 12 through the second conductive bumps 21. The leads 283 exposed on the side surface 135 of the inductor structure 13 are electrically connected to the redistribution layer within the substrate 10 through the solder layer 25. By arranging the wiring structure 28, the transmission of electrical signals between the first functional chip 11 as well as the second functional chip 12 and the substrate 10 can be achieved through the wiring structure 28 pre-embedded into the inductor structure 13. By arranging the leads 283 in the wiring structure 28 on the side surface 135 of the inductor structure 13, the area demand on the substrate 10 can be further reduced, thereby helping to further reduce the size of the package structure. In one example, the wiring structure 28 located at the first main surface 133 of the inductor structure 13 and the wiring structure 28 located at the second main surface 134 are independent of each other (i.e. not connected) to achieve independent control of the first functional chip 11 and the second functional chip 12.

In some embodiments, the package structure further includes: a first surface component 23 mounted on at least the first main surface 133 or the second main surface 134, and the first surface component 23 is electrically connected to the conductive connection pillar 282.

In one example, the plurality of first surface components 23 are respectively mounted on the first main surface 133 and the second main surface 134 of the inductor structure 13, and the first surface components 23 are electrically connected to the conductive connection pillars 282 in the wiring structure 28 to achieve electrical signal transmission between the first surface components 23 and the substrate 10, as well as between the first surface components 23 and the first functional chip 11 or the second functional chip 12 to further improve the integration level of the package structure and expand the function of the package structure.

In some embodiments, the package structure further includes: a heat dissipation structure covering on at least the surface of the first functional chip 11 or the second functional chip 12 facing away from the inductor structure 13 along the second direction D2.

In some embodiments, the heat dissipation structure includes: a first side surface heat sink 16 mounted on the surface of the first functional chip 11 facing away from the inductor structure 13 along the second direction D2; and a second side surface heat sink 20 mounted on the surface of the second functional chip 12 facing away from the inductor structure 13 along the second direction D2.

For example, as shown in FIG. 1, the first side surface heat sink 16 is mounted on the surface of the first functional chip 11 facing away from the inductor structure 13 along the second direction D2 through the first thermal conductive layer 14, and the second side surface heat sink 20 is mounted on the surface of the second functional chip 12 facing away from the inductor structure 13 along the second direction D2 through the second thermal conductive layer 22. In one example, the material of the first thermal conductive layer 14 and the material of the second thermal conductive layer 22 may both be conductive silver paste. By arranging the first side surface heat sink 16 and the second side surface heat sink 20, the heat of the first functional chip 11, the second functional chip 12, and the inductor structure 13 may be dissipated along the second direction D2, reducing the heat accumulation inside the inductor structure 13, the first functional chip 11, and the second functional chip 12, and improving the uniformity of heat dissipation of the package structure, thereby improving the reliability of the package structure and helping to ensure stable performance of the package structure and extending the service life of the package structure.

In some embodiments, the heat dissipation structure further includes: an end heat sink 27 located within the magnetic material layer 131, and disposed on a side of the magnetic material layer 131 facing away from the substrate 10 along the first direction D1; and an internal heat sink 26 located within the magnetic material layer 131, and its one end being connected to the end heat sink 27, and the other end extending out of the side surface of the inductor structure 13.

For example, as shown in FIGS. 1 and 2, the end heat sink 27 is located within the magnetic material layer 131 and exposed on the surface of the magnetic material layer 131.

The inductor structure 13 includes two metal coils 132, and the internal heat sink 26 is disposed between the two metal coils 132, and the end of the internal heat sink 26 is connected to the end heat sink 27 to export the heat inside the inductor structure 13 through the internal heat sink 26 and the end heat sink 27, thereby further improving the heat dissipation performance of the package structure. In one example, the internal heat sink 26 extends to a side of the inductor structure 13 and is connected to the substrate 10 through the solder layer 25, so that the heat inside the inductor structure 13 can also be exported to the substrate 10 through the internal heat sink 26 and the end heat sink 27, thereby further improving the heat dissipation performance of the package structure.

In some embodiments, the heat dissipation structure further includes: a top heat sink 18 located on a side of the inductor structure 13 facing away from the substrate 10 along the first direction D1, and the top heat sink 18 continuously covers on the first side surface heat sink 16, the second side surface heat sink 20, and the end heat sink 27.

For example, as shown in FIG. 1, the top heat sink 18 is mounted on the surface of the inductor structure 13 facing away from the substrate 10 along the first direction D1 through a third thermal conductive layer 19, and the top heat sink 18 continuously covers on the first side surface heat sink 16, the second side surface heat sink 20, and the end heat sink 27, so that the heat within the package structure is exported from the upper part of the package structure, which further reduces heat accumulation within the substrate 10, thereby further improving the heat dissipation performance of the package structure and achieving efficient heat dissipation of the package structure.

In some embodiments, the package structure further includes: a molding layer 17, the molding layer 17 molds at least the inductor structure 13, the first functional chip 11, and the second functional chip 12 to form a magnetic module, and the magnetic module is mounted on the front surface 101 of the substrate 10; and a second surface component 24 mounted on the front surface 101 of the substrate 10, and the second surface component 24 is located outside the magnetic module.

In some implementations, the molding layer 17 continuously molds the inductor structure 13, the first functional chip 11, the second functional chip 12, the first side surface heat sink 16, and the second side surface heat sink 20. Since the molding layer 17 is disposed on opposite sides of the inductor structure 13 along the second direction D2, it helps balance stresses inside the package structure to further improve the performance of the package structure. Additionally, since the covering of the molding layer 17 forms a package-type magnetic module, it is able to improve product reliability. Due to the reduction in the area occupied by the inductor structure 13 on the front surface 101 of the substrate 10, space is reserved for the mounting of the second surface component 24, thereby achieving further improvements in the integration and function of the package structure. In one example, the structure and function of the first surface component 23 are different from the structure and function of the second surface component 24.

In some embodiments, in order to better dissipate heat, the outer surfaces of the first side surface heat sink 16 and the second side surface heat sink 20 may be exposed at the molding layer 17.

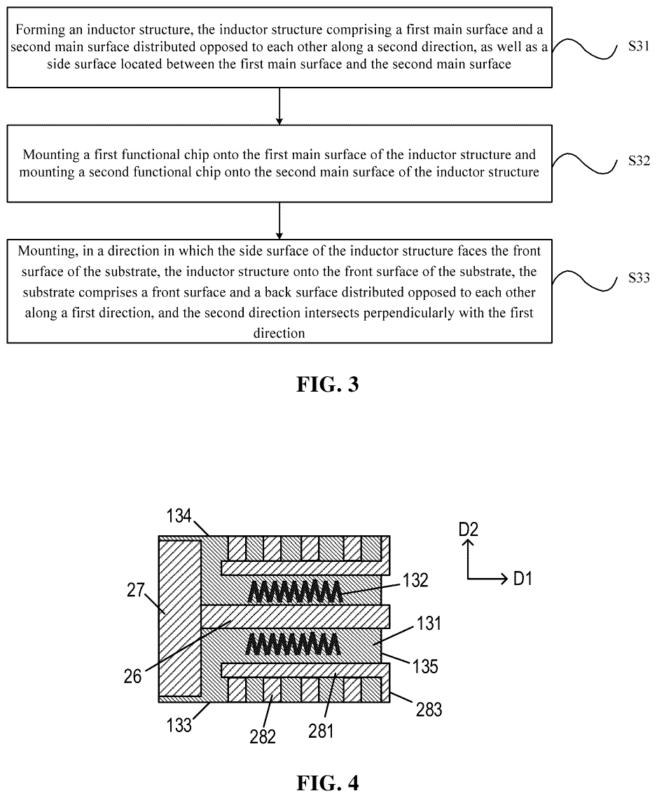

The present implementation also provides a method for forming a package structure. FIG. 3 is a flow schematic diagram of a method for forming the package structure in some implementations of the present disclosure. For schematic diagrams of the package structure formed by the present implementation, reference may be made to FIGS. 1 and 2. As shown in FIGS. 1-3, the method for forming a package structure includes the following steps.

Step S31, forming an inductor structure 13, the inductor structure 13 includes a first main surface 133 and a second main surface 134 oppositely disposed along a second direction D2, as well as a side surface 135 located between the first main surface 133 and the second main surface 134.

Step S32, mounting a first functional chip 11 onto the first main surface 133 of the inductor structure 13, and mounting a second functional chip 12 onto the second main surface 134 of the inductor structure 13.

Step S33, mounting, in a direction in which the side surface 135 of the inductor structure 13 faces the front surface 101 of the substrate 10, the inductor structure 13 onto the front surface of the substrate 10, the substrate 10 includes a front surface 101 and a back surface 102 oppositely disposed along a first direction D1, and the second direction D2 intersects perpendicularly with the first direction D1.

FIG. 4 is a schematic diagram after forming the inductor structure and wiring structure in some implementations of the present disclosure. In some embodiments, as shown in FIG. 1, FIG. 2, and FIG. 4, the steps for forming the inductor structure 13 further include: forming a magnetic material layer 131, a metal coil 132 within the magnetic material layer 131, and a wiring structure 28 within the magnetic material layer 131, the magnetic material layer 131 and the metal coil 132 together serve as the inductor structure 13, and the wiring structure 28 includes: a metal wiring 281 located within the magnetic material layer 131, a plurality of conductive connection pillars 282 electrically connected to the metal wiring 281 and exposed on the first main surface 133 and the second main surface 134, and leads 283 electrically connected to the metal wiring 281 and exposed on the side surface 135 of the inductor structure 13.

In some implementations, in the process of forming the inductor structure 13, the wiring structure 28 is pre-embedded into the inductor structure 13, and the leads 283 in the wiring structure 28 are exposed at the side of the inductor structure 13, which further reduces the size of the package structure while simplifying the manufacturing process of the package structure and improving the manufacturing efficiency of the package structure.

In some embodiments, the steps of mounting the first functional chip 11 onto the first main surface 133 of the inductor structure 13 and mounting the second functional chip 12 onto the second main surface 134 of the inductor structure 13 include: mounting the first functional chip 11 onto the first main surface 133 of the inductor structure 13, and electrically connecting the first functional chip 11 with the conductive connection pillars 282 exposed on the first main surface 133; and mounting the second functional chip 12 onto the second main surface 134 of the inductor structure 13 and electrically connecting the second functional chip 12 with the conductive connection pillars 282 exposed on the second main surface 134.

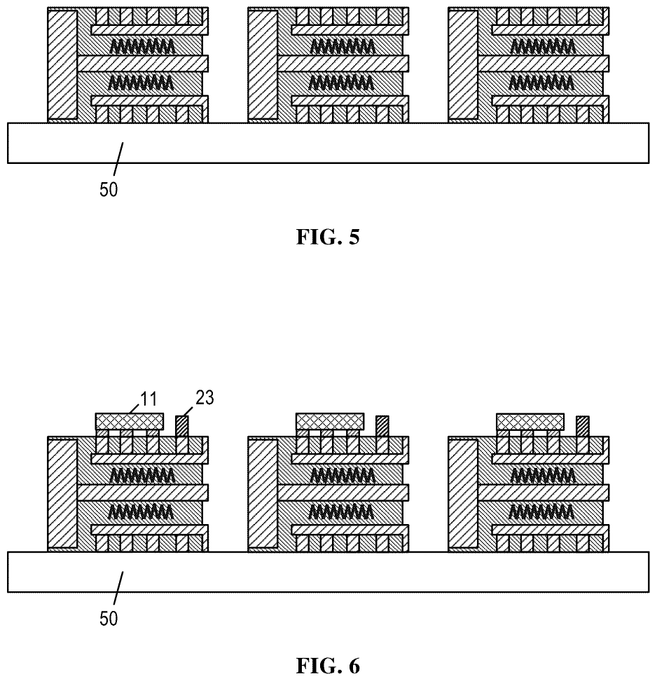

FIG. 5 is a structural schematic diagram after a plurality of inductor structures are arranged on the first carrier board in some implementations of the present disclosure, and FIG. 6 is a structural schematic diagram after the first functional chip is mounted on the first main surface of the inductor structure in some implementations of the present disclosure. In some embodiments, the steps of mounting the first functional chip 11 onto the first main surface 133 of the inductor structure 13 and electrically connecting the first functional chip 11 with the conductive connection pillars 282 exposed on the first main surface 133 further include: mounting the first surface component 23 onto the first main surface 133 of the inductor structure 13, and electrically connecting the first surface component 23 with the conductive connection pillars 282 exposed on the first main surface 133, as shown in FIG. 6.

For example, a plurality of inductor structures 13 with the pre-embedded wiring structure 28 are mounted on the surface of the first carrier board 50 to form a reconfigured body, as shown in FIG. 5. Subsequently, the first functional chip 11 and the first surface component 23 are mounted onto the first main surface 133 of each inductor structure 13, as shown in FIG. 6. For instance, a plurality of first functional chips 11 are flip-flop mounted one-to-one onto the first main surface 133 of the inductor structure 13, and the first functional chips 11 are electrically connected to the conductive connection pillars 282 in the wiring structure 28.

FIG. 7 is a structural schematic diagram after the first side surface heat sink is mounted on the first functional chip in some implementations of the present disclosure. In some embodiments, before mounting the second functional chip 12 onto the second main surface 134 of the inductor structure 13, it further includes the following steps: mounting the first side surface heat sink 16 onto the surface of the first functional chip 11 facing away from the inductor structure 13 along the second direction D2, as shown in FIG. 7.

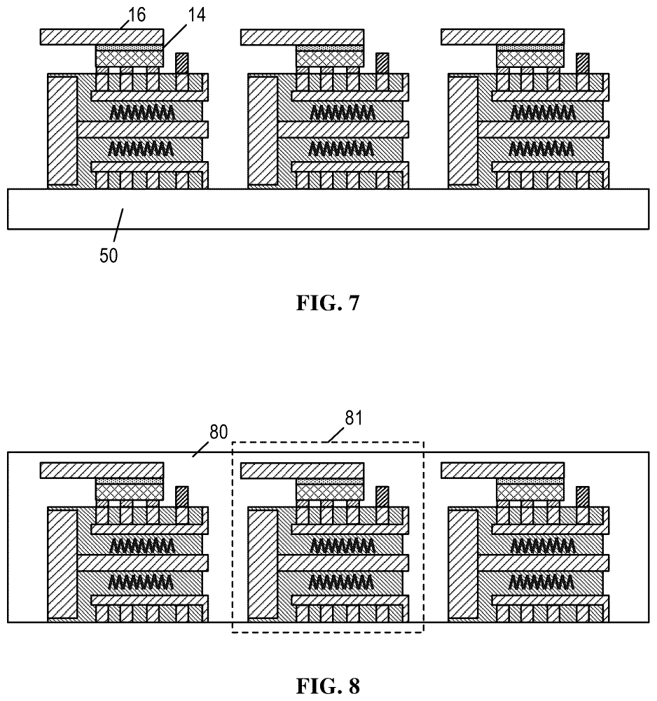

FIG. 8 is a structural schematic diagram after forming the first molding layer in some implementations of the present disclosure. In some embodiments, before mounting the second functional chip 12 onto the second main surface 134 of the inductor structure 13, it further includes the following steps:
forming a first molding layer 80 molding the inductor structure 13, the first functional chip 11, and the first side surface heat sink 16, as shown in FIG. 8.

For example, the first side surface heat sink is mounted on the surface of the first functional chip 11 facing away from the inductor structure 13 through a first thermal conductive layer 14, as shown in FIG. 7. Subsequently, the first molding layer 80 continuously molding the inductor structure 13, the first functional chip 11, and the first side surface heat sink 16 is formed on the first carrier board 50, and a plurality of first molding bodies 81 are formed. Afterwards, the first carrier board 50 is removed by the manner of debonding or peeling to obtain the structure shown in FIG. 8.

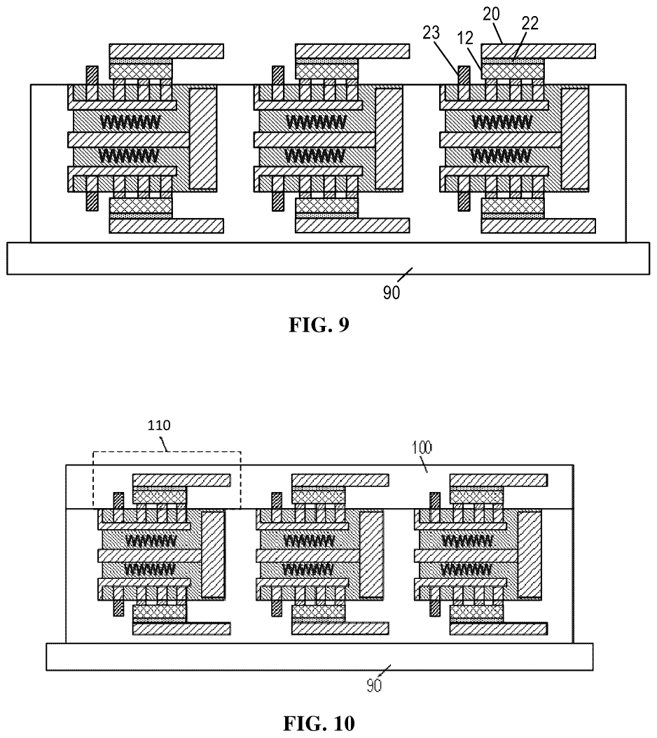

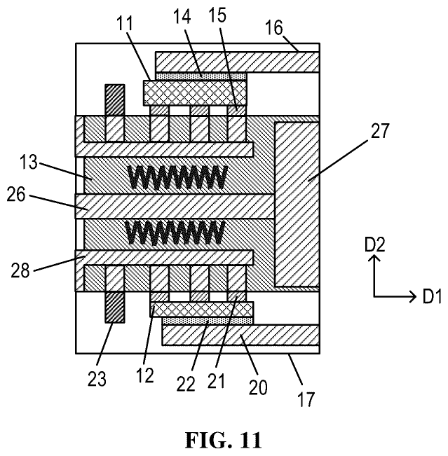

FIG. 9 is a structural schematic diagram after mounting the second functional chip on the second main surface of the inductor structure in some implementations of the present disclosure; FIG. 10 is a structural schematic diagram after forming the second molding layer in some implementations of the present disclosure; and FIG. 11 is a structural schematic diagram of a single package unit in some implementations of the present disclosure. In some embodiments, the steps of mounting the second functional chip 12 onto the second main surface 134 of the inductor structure 13 include: mounting the second side surface heat sink 20 onto the surface of the second functional chip 12 facing away from the inductor structure 13 along the second direction D2, as shown in FIG. 9; and forming a second molding layer 100 covering the first molding layer 80 and molding the second functional chip 12 and the second side surface heat sink 20, as shown in FIG. 10. The first molding layer 80 and the second molding layer 100 together constitute the molding layer 17 (referring to FIG. 1).

For example, after removing the first carrier board 50, the first molding body is mounted on the second carrier board 90 along a direction in which the second main surface 134 of the inductor structure 13 faces away from the second carrier board 90. Afterwards, the second functional chip 12 and the first surface component 23 are mounted onto the second main surface 134 of each inductor structure 13. For instance, a plurality of second functional chips 12 are flip-flop mounted one-to-one onto the second main surface 134 of the inductor structure 13, and the second functional chips 12 are electrically connected to the conductive connection pillars 282 in the wiring structure 28. Subsequently, the second side surface heat sink 20 is mounted on the surface of the second functional chip 12 facing away from the inductor structure 13 through the second thermal conductive layer 22, as shown in FIG. 9. Then, the second molding layer 100 continuously molding the second functional chips 12 and the second side surface heat sinks 20 is formed above the first molding layer 80, and a plurality of second molding bodies 110 are obtained, as shown in FIG. 10.

In some embodiments, after mounting, in a direction in which the side surface 135 of the inductor structure 13 faces the front surface 101 of the substrate 10, the inductor structure 13 onto the front surface 101 of the substrate 10, it further includes the following steps:
mounting a top heat sink 18 on a side of the inductor structure 13 facing away from the substrate 10, and the top heat sink 18 continuously covers the first side surface heat sink 16, the second side surface heat sink 20, and the molding layer 17.

For example, after forming the second molding layer 100, a plurality of package units are obtained, each package unit including a first molding body 81 and a second molding body 110 stacked on the surface of the first molding body 81. After separating adjacent package units through a cutting process and removing the second carrier board 90, independent package units as shown in FIG. 11 are obtained, i.e., a package-type magnetic module is formed. Subsequently, the magnetic module is mounted on the front surface 101 of the substrate 10, and the top heat sink 18 is mounted on the surface of the magnetic module facing away from the substrate 10, then the structure shown in FIG. 1 is obtained.

In the package structure and the method for forming the same provided by the present disclosure, by forming an inductor structure including a first main surface and a second main surface oppositely disposed along a second direction, as well as a side surface located between the first main surface and the second main surface, and by mounting the inductor structure on the front surface of the substrate in a direction in which the side surface of the inductor structure is opposed to the front surface of the substrate, the inductor structure is vertically mounted on the substrate; the first functional chip and the second functional chip are respectively mounted on the first main surface and the second main surface of the inductor structure, on the one hand, in the package structure integrating an inductor structure and a plurality of functional chips, there is no need to stack a plurality of substrates, achieving simplification of the package structure; on the other hand, the inductor structure is vertically mounted on the substrate, thereby reducing the occupation of the substrate area, thereby helping to further reduce the size of the package structure and improving the integration level of the package structure.

The above is only the some implementations of the present disclosure, it should be noted that those skilled in the art may further make various improvements and refinements without departing from the principles of the present disclosure, and these improvements and refinements should also be considered to be within the scope of protection of the present disclosure.

What is claimed is:

1. A package structure, comprising:
a substrate comprising a front surface and a back surface oppositely disposed along a first direction;
an inductor structure comprising: a first main surface and a second main surface oppositely disposed along a second direction, and a side surface located between the first main surface and the second main surface, wherein the side surface of the inductor structure is mounted on the front surface of the substrate along the first direction, and the second direction is perpendicular to the first direction;
a first functional chip mounted on the first main surface of the inductor structure; and
a second functional chip mounted on the second main surface of the inductor structure.

2. The package structure according to claim 1, further comprising:
a wiring structure located inside the inductor structure and extending to the side surface of the inductor structure, wherein the wiring structure is electrically connected to the first functional chip, the second functional chip, and the substrate.

3. The package structure according to claim 2, wherein:
the inductor structure comprises:
a magnetic material layer; and
a metal coil located within the magnetic material layer; and
the wiring structure comprises:
a metal wiring located within the magnetic material layer;
a plurality of conductive connection pillars electrically connected to the metal wiring and exposed on the first main surface and the second main surface; and
leads electrically connected to the metal wiring and exposed on the side surface of the inductor structure,
wherein the conductive connection pillars are electrically connected to the first functional chip and the second functional chip, and the leads are electrically connected to the substrate.

4. The package structure according to claim 3, further comprising:
a first surface component mounted on at least one of the first main surface or the second main surface, wherein the first surface component is electrically connected to the conductive connection pillars.

5. The package structure according to claim 3, further comprising:
a heat dissipation structure covering at least a first surface of the first functional chip or a second surface of the second functional chip facing away from the inductor structure along the second direction.

6. The package structure according to claim 5, wherein the heat dissipation structure comprises:
a first side surface heat sink mounted on the first surface of the first functional chip facing away from the inductor structure along the second direction; and
a second side surface heat sink mounted on the second surface of the second functional chip facing away from the inductor structure along the second direction.

7. The package structure according to claim 6, wherein the heat dissipation structure further comprises:
an end heat sink located within the magnetic material layer and disposed on a side of the magnetic material layer facing away from the substrate along the first direction; and
an internal heat sink located within the magnetic material layer, wherein one end of the internal heat sink is connected to the end heat sink and the other end of the internal heat sink extends out of the side surface of the inductor structure.

8. The package structure according to claim 7, wherein the heat dissipation structure further comprises:
a top heat sink disposed on a side of the inductor structure facing away from the substrate along the first direction, wherein the top heat sink continuously covers the first side surface heat sink, the second side surface heat sink, and the end heat sink.

9. The package structure according to claim 1, further comprising:
a molding layer molding at least the inductor structure, the first functional chip, and the second functional chip to form a magnetic module, wherein the magnetic module is mounted on the front surface of the substrate; and
a second surface component mounted on the front surface of the substrate and located outside the magnetic module.

10. A method for forming a package structure, comprising:
providing a substrate comprising a front surface and a back surface oppositely disposed along a first direction;
forming an inductor structure, wherein the inductor structure comprises a first main surface and a second main surface oppositely disposed along a second direction, and a side surface located between the first main surface and the second main surface, and wherein the second direction is perpendicular to the first direction;
mounting a first functional chip on the first main surface of the inductor structure;
mounting a second functional chip on the second main surface of the inductor structure; and
mounting the side surface of the inductor structure on the front surface of the substrate along the first direction.

11. The method for forming a package structure according to claim 10, wherein forming the inductor structure comprises:
forming a magnetic material layer;
forming a metal coil located within the magnetic material layer; and
forming a wiring structure located within the magnetic material layer,
wherein the magnetic material layer and the metal coil form the inductor structure;
the wiring structure comprises:
a metal wiring located within the magnetic material layer;
a plurality of conductive connection pillars electrically connected to the metal wiring and exposed on the first main surface and the second main surface; and
leads electrically connected to the metal wiring and exposed on the side surface of the inductor structure.

12. The method for forming a package structure according to claim 11, wherein:
mounting a first functional chip on the first main surface of the inductor structure and mounting a second functional chip on the second main surface of the inductor structure comprise:
mounting the first functional chip on the first main surface of the inductor structure and electrically connecting the first functional chip to the conductive connection pillars exposed on the first main surface; and
mounting the second functional chip on the second main surface of the inductor structure and electrically connecting the second functional chip to the conductive connection pillars exposed on the second main surface.

13. The method for forming a package structure according to claim 12, wherein the mounting the first functional chip on the first main surface of the inductor structure and electrically connecting the first functional chip to the conductive connection pillars exposed on the first main surface further comprise:
mounting a first surface component on the first main surface of the inductor structure and electrically connecting the first surface component to the conductive connection pillars exposed on the first main surface.

14. The method for forming a package structure according to claim 12, wherein before mounting the second functional chip on the second main surface of the inductor structure, the method further comprises:
mounting a first side surface heat sink on a surface of the first functional chip facing away from the inductor structure along the second direction.

15. The method for forming a package structure according to claim 14, wherein before mounting the second functional chip on the second main surface of the inductor structure, the method further comprises:
forming a first molding layer molding at least the inductor structure, the first functional chip, and the first side surface heat sink to form a magnetic module.

16. The method for forming a package structure according to claim 15, wherein mounting the second functional chip on the second main surface of the inductor structure further comprises:
mounting a second side surface heat sink on a surface of the second functional chip facing away from the inductor structure along the second direction; and
forming a second molding layer covering the first molding layer and molding the second functional chip and the second side surface heat sink, wherein the first molding layer and the second molding layer form a molding layer.

17. The method for forming a package structure according to claim 16, wherein after mounting the side surface of the inductor structure on the front surface of the substrate along the first direction, the method further comprises:
mounting a top heat sink on a side of the inductor structure facing away from the substrate along the first direction, wherein the top heat sink continuously covers the first side surface heat sink, the second side surface heat sink, and the molding layer.

18. The method for forming a package structure according to claim 11, wherein forming the inductor structure comprises:
forming an end heat sink located within the magnetic material layer and disposed on a side of the magnetic material layer facing away from the substrate along the first direction; and
forming an internal heat sink located within the magnetic material layer, wherein one end of the internal heat sink is connected to the end heat sink and the other end of the internal heat sink extends out of the side surface of the inductor structure.

19. The method for forming a package structure according to claim 14, further comprising:
providing a first carrier board, wherein the first side surface heat sink is formed on the first carrier board;
removing the first carrier board; and
providing a second carrier board, wherein the first molding layer is mounted on the second carrier board.

20. The method for forming a package structure according to claim 19, wherein the first carrier board is removed by debonding or peeling.
